(19) United States
(12) Patent Application Publication
(10) Pub. No.: US 2011/0188190 A1
(43) Pub. Date: Aug. 4, 2011

(54) ELECTRONIC APPARATUS HAVING REPLACEABLE INPUT DEVICE

(75) Inventor: Tatsuya MIYAIRI, Fussa-shi (JP)

(73) Assignee: KABUSHIKI KAISHA TOSHIBA, Tokyo (JP)

(21) Appl. No.: 13/009,689

(22) Filed: Jan. 19, 2011

(30) Foreign Application Priority Data
Jan. 29, 2010 (JP) 2010-019683

(51) Int. Cl. H05K 7/00

(52) U.S. Cl. 361/679.09

(57) ABSTRACT

An electronic apparatus includes: a main body comprising electronic components; a first input device configured to be mounted on the main body; a first connector configured to connect the first input device to the electronic components, the first connector having a first assured number of times of insertion and removal; and a second connector configure to connect a second input device to the electronic components when the second input device is mounted on the main body in place of the first input device, the second connector having a second assured number of times of insertion and removal, which is larger than the first assured number of times of insertion and removal.

### CROSS-REFERENCE TO THE RELATED APPLICATION(S)

The present application is based upon and claims priority from prior Japanese Patent Application No. 2010-019683, filed on Jan. 29, 2010, the entire contents of which are incorporated herein by reference.

### FIELD

Embodiments described herein generally relate to an electronic apparatus having a configuration for easily replacing an input device.

### BACKGROUND

Electronic apparatus such as notebook personal computers (PCs) in which an input device (e.g., keyboard) is incorporated in the main body are known. The user of an electronic apparatus in which a keyboard is integrated with the main body apparatus may consider replacing the keyboard that has been incorporated since the purchase of the electronic apparatus with another one when, for example, only the keyboard has failed (the electronic apparatus main body has no problem) or the user wants to change the keyboard design or incorporate a keyboard that is extended in functionality.

However, in many cases, in electronic apparatus such as general notebook PCs, replacement of only the keyboard is not assumed from the viewpoint of manufacturing cost and other factors. Furthermore, the keyboard replacement work is difficult to ordinary users and the keyboard or the main body may fail due to an error occurring in replacement work.

In view of the above, as for the keyboard attaching method, an information terminal, its keyboard unit, and a system unit were proposed in which the keyboard unit can be attached to the system unit merely by engaging keyboard-side engagement members with system-unit-side engagement members. An example of such configuration is disclosed in JP-A-2002-149305 (counterpart U.S. publication is: US 2002/0047832 A1).

In the configuration disclosed in JP-A-2002-149305, no reference is made to a method for attaching (or removing) connectors to (or from) the system unit.

For example, in electronic apparatus such as notebook PCs, in general, the keyboard as an input device is connected to the main body apparatus by an FPC (flexible printed circuits) which is a bendable circuit board and, to this end, an FPC connector is provided in the electronic apparatus main body. An FPC terminal and the FPC connector are connected to each other, whereby a manipulation of the user on the keyboard is input to the electronic apparatus main body. To reduce the cost, in general, the keyboard is not equipped with a keyboard controller and the electronic apparatus main body scans matrix-arranged switches. This requires a large number of signal lines in the FPC. A signal obtained by a scan is converted by a processor such as a keyboard controller incorporated in the electronic apparatus main body into a key code, which is supplied to other modules in the electronic apparatus as a prescribed input signal. Since the FPC has a large number of signal lines as mentioned above and the FPC itself is not configured taking its insertion and removal into consideration, from the viewpoint of the assurance of performance the insertion and removal of the FPC is not desirable acts to be done by the user.

In addition, existing FPC connectors may not be compatible with replacement keyboards that are, for example, extended in functionality, because of a shortage of signal lines. In this case, an intelligent keyboard controller and a connector for connecting a keyboard may need to be provided additionally in the keyboard.

### BRIEF DESCRIPTION OF THE DRAWINGS

A general configuration that implements the various features of the present invention will be described with reference to the drawings. The drawings and the associated descriptions are provided to illustrate embodiments of the invention and not to limit the scope of the invention.

FIG. 1 is a perspective view of an example notebook computer according to an embodiment of the present invention.

FIG. 2 is an exploded perspective view showing an example state that a first keyboard is removed from the notebook computer according to the embodiment of the invention.

FIG. 3 is a perspective view showing an example back surface structure of the first keyboard used in the embodiment.

FIG. 4 is a perspective view showing an example back surface structure of a second keyboard used in the embodiment.

### DETAILED DESCRIPTION

According to the embodiments described herein, there is provided an electronic apparatus including: a main body comprising electronic components; a first input device configured to be mounted on the main body; a first connector configured to connect the first input device to the electronic components, the first connector having a first assured number of times of insertion and removal; and a second connector configure to connect a second input device to the electronic components when the second input device is mounted on the main body in place of the first input device, the second connector having a second assured number of times of insertion and removal, which is larger than the first assured number of times of insertion and removal.

Embodiments according to the present invention will be described in detail with reference to the accompanying drawings. The scope of the claimed invention should not be limited to the examples illustrated in the drawings and those described in below.

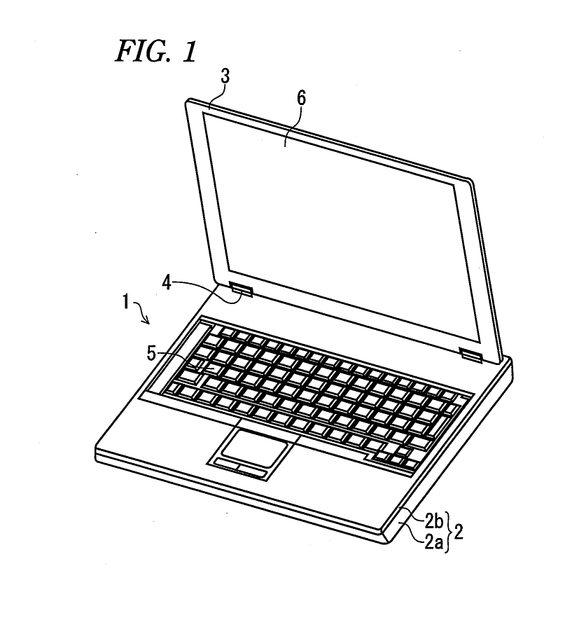

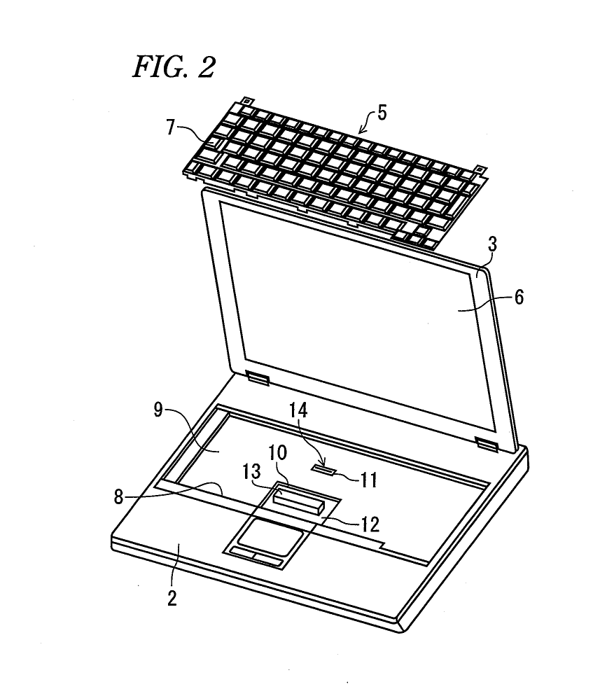

FIG. 1 is a perspective view of an example notebook computer according to the embodiment. FIG. 2 is an exploded perspective view showing an example state that a first keyboard is removed from the notebook computer according to the embodiment.

As shown in FIGS. 1 and 2, the notebook computer (electronic apparatus) 1 has a main body 2 and a display unit 3 which is connected rotatably to the main body 2 by hinges 4. The main body 2 has a bottom case 2a and a top case 2b which is joined to the bottom case 2a. The top case 2b is provided with a keyboard mounting portion (hereinafter referred to simply as amounting portion) 8 on which the first keyboard 5 or a second keyboard 28 for replacement is (is to be) mounted detachably.

The main body 2 of the notebook computer 1 according to the embodiment is designed so that the first keyboard 5 and the second keyboard 28 can be replaced by each other. The first keyboard 5 is a keyboard that is incorporated in the notebook computer 1 originally and has plural keys 7. The first keyboard 5 is configured so as to be connected to the notebook computer 1 by a flexible printed wiring board (hereinafter referred to as FPC) 22. The notebook computer 1 is equipped with a keyboard controller for scanning the switches of the first keyboard 5 to check their manipulation states and thereby detecting an input signal from the first keyboard 5. The user can attach the second keyboard 28 for replacement to the mounting portion 8 from which the first keyboard 5 has been removed. Assuming replacement with still another keyboard, the second keyboard 28 is equipped with a USB (universal serial bus) connector (second USB connector 32). The USB is a general-purpose interface that is designed with assumption of repeated insertion/removal actions. The second USB connector 32 can be electrically connected to a first USB connector 14 that is provided adjacent to the mounting portion 8 of the main body 2. The second keyboard 28 may be equipped with a keyboard controller for detecting an input signal generated by itself. Although the embodiment employs the second keyboard 28 having the USB interface, other interfaces such as IEEE 1394, PCI-Express, and eSATA that assume repeated insertion/removal actions may also be employed.

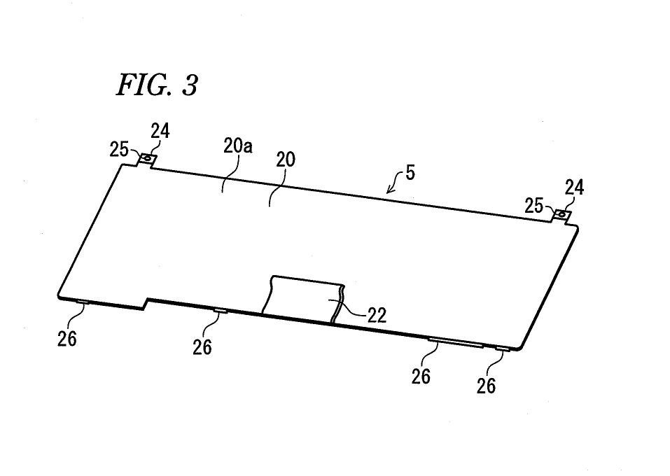

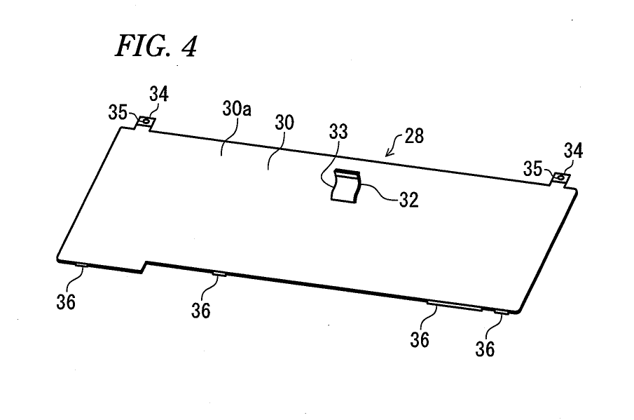

The FPC 22 and the second USB connector 32 that are provided in the first keyboard 5 and the second keyboard 28 will be described later in detail with reference to FIGS. 3 and 4, respectively.

The mounting portion 8 has such a size that each of the first keyboard 5 and the second keyboard 28 can be mounted thereon. The display unit 3 incorporates a display device 6, and a circuit board 12 (described later) is disposed inside the main body 2. In the embodiment, the back surface (i.e., the surface opposite to the front surface where keys are arranged) of each of the first keyboard 5 and the second keyboard 28 is provided with the connection members (FPC 22 and second USB connector 32) for electrical connection to the notebook computer 1.

The mounting portion 8 has a plate-like bottom wall 9. When the first keyboard 5 or the second keyboard 28 is mounted on the mounting portion 8, the bottom surface of the first keyboard 5 or the second keyboard 28 contacts the bottom wall 9. The bottom wall 9 may be integral with the top case 2b. An alternative structure is possible in which the mounting portion 8 is formed with a large opening and a sheet metal member, for example, that is separate from the top case 2b and serves as the bottom wall 9 is attached to the portion around the opening so as to close the opening.

The bottom wall 9 is formed with a first opening 10 and a second opening 11. At least part of the circuit board 12 which is provided inside the main body 2 is exposed through the first opening 10. An FPC connector 13 to which the FPC 22 can be attached is mounted on the circuit board 12 at such a position as to be exposed through the first opening 10. The first USB connector 14 for electrical connection to the second keyboard 28 is exposed through the second opening 11. The sizes of the first opening 10 and the second opening 11 can be determined arbitrarily according to the design of the notebook computer 1.

FIG. 3 is a perspective view showing an example back surface structure of the first keyboard 5 used in the embodiment.

The first keyboard 5 has a sheet metal member 20 having approximately the same size as the mounting portion 8. Plural engagement pieces 26 are integral with the front edge (corresponding to the front portion of the mounting portion 8) of the sheet metal member 20. Plural fixing pieces 24 are integral with the rear edge (corresponding to the rear portion of the mounting portion 8) of the sheet metal member 20. Each fixing piece 24 is formed with a screw hole 25 for insertion of a screw.

A bottom surface 20a of the sheet metal member 20 is provided with the FPC 22. The FPC 22 is a flexible printed wiring board for exchanging electrical signal between devices connected to it. The FPC 22 is incorporated in the first keyboard 5 and electrically connected to a circuit board (not shown) for converting a user input that is made through each of the plural keys 7 into an electrical signal.

Originally, the first keyboard 5 is attached to the main body 2 of the notebook computer 1. The FPC 22 of the first keyboard 5 is connected to the FPC connector 13 which is provided on the circuit board 12 of the main body 2. The first keyboard 5 and the circuit board 12 are electrically connected to each other by the FPC 22. If the user wants to replace the first keyboard 5 for a certain reason, he or she can remove it at this connecting point. Therefore, the user can switch the keyboard of the notebook computer 1 from the first keyboard 5 to the second keyboard 28.

To remove the first keyboard 5 from the main body 2, first, the screws (not shown) are disengaged from the screw holes 25 of the fixing pieces 24 which are formed on the rear edge of the first keyboard 5. The plural engagement pieces 26 which are formed on the front edge of the first keyboard 5 are inserted in respective engagement holes (not shown) of the mounting portion 8. The first keyboard 5 can be removed by rotating it with the engaging points of the engagement pieces 26 and the engagement holes as supporting points so that the rear edge of the first keyboard 5 goes up and then pulling the engagement pieces 26 out of the engagement holes. When the first keyboard 5 is removed, the FPC 22 is pulled out of the FPC connector 13, whereby the first keyboard 5 is electrically disconnected from the circuit board 12.

The second keyboard 28 for replacement will be described below with reference to FIG. 4.

FIG. 4 is a perspective view showing an example back surface structure of the second keyboard 28 used in the embodiment.

The second keyboard 28 has a sheet metal member 30 having approximately the same size as the mounting portion 8. Plural engagement pieces 36 are integral with the front edge (corresponding to the front portion of the mounting portion 8) of the sheet metal member 30. Plural fixing pieces 34 are integral with the rear edge (corresponding to the rear portion of the mounting portion 8) of the sheet metal member 30. Each fixing piece 34 is formed with a screw hole 35 for insertion of a screw.

A bottom surface 30a of the sheet metal member 30 is formed with an opening 33 through which the second USB connector 32 is exposed. The second USB connector 32 is a connector which can exchange signals according to the USB standard and survive a large number of insertion/removal actions. The second USB connector 32 enables exchange of electrical signals when connected to the first USB connector 14. The second USB connector 32 is electrically connected to a circuit board (not shown) for converting a user input that is made through each of the plural keys into an electrical signal.

After the first keyboard 5 is removed from the main body 2 of the notebook computer 1, the second keyboard 28 can be attached to the main body 2. At this time, the second keyboard 28 is electrically connected to the notebook computer 1 by the first USB connector 14 and the second USB connector 32. The second keyboard 28 and the main body 2 can exchange electrical signals by connecting the second USB connector 32 to the first USB connector 14. Since the USB connectors 14 and 32, the FPC 22, and the FPC connector 13 are provided adjacent to the bottom surface 20a or 30a of the keyboard 5 or 28 or the bottom wall 9 of the mounting portion 8, they are invisible from the outside in the state that the first keyboard 5 or the second keyboard 28 is attached to the notebook computer 1 and hence do not impair the appearance of the notebook computer 1 as a whole to which the keyboard 5 or 28 is attached.

To mount the second keyboard 28 on the mounting portion 8, the plural engagement pieces 36 on the front edge of the second keyboard 28 are inserted into the respective engagement holes (not shown) of the mounting portion 8. The second keyboard 28 is mounted on the mounting portion 8 by rotating the second keyboard 28 with the engaging points of the engagement pieces 36 and the engagement holes as supporting points so that the rear edge of the second keyboard 28 goes down. Then, the fixing pieces 34 are fixed to the mounting portion 8 by screwing screws (not shown) into the respective screw holes 35 of the fixing pieces 34. When the second keyboard 28 is mounted on the mounting portion 8 in the above-described manner, the second USB connector 32 which is exposed through the opening 33 of the bottom surface 30a of the second keyboard 28 is inserted into the first USB connector 14 which is exposed through the second opening 11 of the bottom wall 9 of the mounting portion 8. As a result, the notebook computer 1 can receive electrical signals from the second keyboard 28.

As described above, the first keyboard 5 is electrically connected to the notebook computer 1 by the FPC 22. Ordinary users are not accustomed to connecting (inserting) the FPC 22 which is thin and wide to (into) the FPC connector 13, and such an act is not recommendable in terms of the guarantee of quality such as avoidance of a contact failure. In the embodiment, the notebook computer 1 according to the embodiment is equipped, adjacent to the mounting portion 8, with the first USB connector 14 in addition to the FPC connector 13, and the user connects the second keyboard 28 (replacement keyboard) to the notebook computer 1 using the USB connector 14 which is designed so as to facilitate connection work and survive repeated insertion/removal actions. This allows the user to easily replace the first keyboard 5 with the second keyboard 28 when, for example, the first keyboard 5 has failed.

While incorporating a keyboard controller in the second keyboard 28 increases its cost, the following merits are obtained. That is, the price at shipment is lowered because the first keyboard 5 is connected to the FPC connector 13 at the time of shipment. A user who wants replacement of the first keyboard 5 benefits from easy and reliable keyboard replacement by himself or herself though the user suffers a slight cost increase. Furthermore, future enhancement in functionality is enabled in a flexible manner.

In the embodiment, the first keyboard 5 and the second keyboard 28 need not be the same in the points other than described above; for example, they may have different key arrangements (e.g., the second keyboard 28 for replacement may be provided with a ten-key unit). The second keyboard 28 may have an extended function that is not provided in the first keyboard 5, such as a touch pad. In the embodiment, the second keyboard 28 incorporates a keyboard controller and is connected to the notebook computer 1 by USB interface. This allows the notebook computer 1 to accommodate the second keyboard 28 even if it has an extended function.

In the embodiment, the notebook computer 1 has the connectors 13 and 14 as members for electrical connection to the first keyboard and the second keyboard 28, respectively. Therefore, the notebook computer 1 can continue to be used even if the keyboard in use has failed. Furthermore, even if one of the connectors 13 and 14 of the notebook computer 1 is damaged, the notebook computer 1 can continue to be used if a keyboard that can be connected to the notebook computer 1 by the other connector is prepared.

Furthermore, the first keyboard 5 and the second keyboard 28 employ the same method of physical fixing to the notebook computer 1. This allows the user to attach the second keyboard 28 by studying the manner of removal of the first keyboard 5. The manner of attaching the second keyboard 28 is thus easy to understand, and hence the user can attach the second keyboard 28 easily.

Although the embodiment employs the USB connectors 14 and 32 for electrical connection between the notebook computer 1 and the second keyboard 28 for replacement, the invention is not limited to such a case. Another standard that enables transmission of a signal that is output from a keyboard controller may be employed for connection of the second keyboard.

In the notebook computer 1 according to the embodiment, the input device can be replaced from the built-in keyboard 5 to a different keyboard.

Although the embodiments according to the present invention have been described above, the present invention may not be limited to the above-mentioned embodiments but can be variously modified. Components disclosed in the aforementioned embodiments may be combined suitably to form various modifications. For example, some of all components disclosed in the embodiments may be removed or may be appropriately combined.

Additional advantages and modifications will readily occur to those skilled in the art. Therefore, the invention in its broader aspects may not be limited to the specific details and representative embodiments shown and described herein. Accordingly, various modifications may be made without departing from the spirit or scope of the general inventive concept as defined by the appended claims and their equivalents.

What is claimed is:

1. An electronic apparatus comprising:
a housing comprising electronic components;
a first input device on the housing;
a first connector configured to connect the first input device and the electronic components, the first connector being configured to be inserted and removed at least a first number of times; and
a second connector capable of connecting a second input device and the electronic components when the second input device is on the housing in place of the first input device, the second connector being configured to be inserted and removed at least a second number of times, which is larger than the first number of times.

2. The apparatus of claim 1,
wherein a number of lines of the second connector is less than a number of lines of the first connector and a connector shape of the second connector different from that of the first connector.

3. The apparatus of claim 1,
wherein the first input device is a first keyboard device comprising a plurality of first key switches and configured to output conduction states of the first key switches to the electronic components according to a first interface standard, and
wherein the second input device is a second keyboard device comprising a plurality of second key switches and a controller and configured to output detection results of conduction states of the second key switches to the electronic components according to a second interface standard.

4. The apparatus of claim 1,
wherein the first input connector and the second input connector are within an area hidden from outside when the first input device and the second input device are on the housing.

5. The apparatus of claim 1,
wherein the first input connector is a flexible print circuit type connector.

6. The apparatus of claim 1,
wherein the second input connector is a universal serial bus connector.

7. The apparatus of claim 1,
wherein the second input connector is an eSATA connector.

8. The apparatus of claim 1,
wherein the second input connector is a PCI Express connector.

9. The apparatus of claim 1,
wherein the second input connector is an IEEE 1394 connector.

10. A method of attaching an internal input device and an external input device to an electronic apparatus and detaching the internal input device and the external input device from the electronic apparatus, comprising:
connecting between the internal input device on a housing and electronic components in the housing with a first connector, the first connector being configured to be inserted and removed at least a first number of times; and
connecting between the external input device and the electronic components when the external input device is on the housing in place of the internal input device with a second connector, the second connector being configured to be inserted and removed at least a second number of times, which is larger than the first number of times.

11. The method of claim 1,
wherein the first input device is a first keyboard device comprising a plurality of first key switches; and
wherein the second input device is a second keyboard device comprising a plurality of second key switches and a controller,
the method further comprising:
outputting conduction states of the first key switches from the first input device to the electronic components according to a first interface standard; and
outputting detection results of conduction states of the second key switches from the second input device to the electronic components according to a second interface standard.

12. A portable computer comprising:
a casing comprising electronic components;
an internal input device on the casing;
a first connector at a first port between the electronic components and the internal input device;
a second connector at a second port configured to connect the electronic components and an external input device;
wherein the casing is configured to attach the external input device in place of the first internal input device;
wherein the first connector is configured to withstand a first number of times of removals; and
wherein the second connector is configured to withstand a second number of times of removals, the second number being larger than the first number.
